(19) United States
(12) Patent Application Publication
(10) Pub. No.: US 2008/0054373 A1
(43) Pub. Date: Mar. 6, 2008

(54) POWER SEMICONDUCTION DEVICE AND CIRCUIT MODULE HAVING SUCH POWER SEMICONDUCTION DEVICE

(75) Inventors: Yin-Yuan Chen, Taoyuan (TW); Chen-Yu Yu, Taoyuan (TW)

Correspondence Address: MADSON & AUSTIN, 15 WEST SOUTH TEMPLE, SUITE 900, SALT LAKE CITY, UT, 84101, US

(73) Assignee: Delta Electronics, Inc., Taoyuan (TW)

(21) Appl. No.: 11/675,511

(22) Filed: Feb. 15, 2007

(30) Foreign Application Priority Data
Sep. 6, 2006 (TW) 095132951

(51) Int. Cl. H01L 29/78; H01L 23/52

(52) U.S. Cl. 257/401; 257/603; 257/691; 257/E23.141; 257/E29.255; 257/E29.327

(57) ABSTRACT

A power semiconductor device includes a semiconductor chip, a first conductive piece, a second conductive piece and an encapsulating resin. The semiconductor chip includes a first electrode and a second electrode. The first conductive piece is in contact with the first electrode of the semiconductor chip. The second conductive piece is in contact with the second electrode of the semiconductor chip. The encapsulating resin covers the semiconductor chip, a portion of the first conductive piece and a portion of the second conductive piece, such that a conducting current is transmitted through the first conductive piece and the second conductive piece to form a power diode. In an embodiment, the power semiconductor device further includes a conductive pin and a third electrode. The third electrode is disposed on the first surface or the second surface of the semiconductor chip and electrically connected to conductive pin, and a portion of the conductive pin is encapsulated by the encapsulating resin so as to form a power MOSFET.

### FIELD OF THE INVENTION

The present invention relates to a power semiconductor device, and more particularly to a power semiconductor device with high conducting current and low thermal resistance. The present invention also relates to a circuit module having such a power semiconductor device.

### BACKGROUND OF THE INVENTION

Recently, power semiconductor devices such as power metal oxide semiconductor field effect transistors (power FETs) or power diodes are widely used in power supply circuits to provide for example the switching functions. For achieving advance in their power and performance, the power semiconductor devices are developed toward high conducting current and low thermal resistance.

Referring to FIG. 1, a cross-sectional view of a power semiconductor device called DirectFET developed by International Rectifier Corporation is illustrated. The power semiconductor device 1 is designed for high current DC/DC converter and mounted on a circuit board 2 according to a surface mount technology (SMT). The power semiconductor device 1 includes a semiconductor chip 11 and a metal cap 12. The semiconductor chip 11 includes a gate region 13, a source region 14 and a drain region 15. The gate region 13 and the source region 14 are arranged on the bottom of the semiconductor chip 11 and attached onto corresponding contact portions 21 on the circuit board 2 via an adhesive layer 3, so that the gate region 13 and the source region 14 are electrically connected to the circuit board 2. The metal cap 12 is made of electrical conductive material that is electrical contact with the drain region 15 via silver glue. The metal cap 12 have first terminals in contact with the drain region 15 and second terminals attached onto corresponding contact portions 21 on the circuit board 2 via the adhesive layer 3, so that the drain region 15 is electrically connected to the circuit board 2.

During operation of the power semiconductor device 1, the semiconductor chip 11 may generate energy in the form of heat, which will be conducted away in two major directions. One is conducted to the metal cap 2 that is optional to attach heat sink (not shown) in order to enhance cooling. The second path is toward the circuit board 2. The circuit board 2 becomes a heat sink of the semiconductor chip 11 meanwhile generates heat internally because of current conduction and Joule heating. Both heat generation in the semiconductor chip 11 and the circuit board 2 result in high operation temperature of the semiconductor chip 11 and the circuit board 2 that limit the conducting current allowable to be transmitted through the power semiconductor devices.

Therefore, there is a need to provide a power semiconductor device having increased heat-dissipating efficiency and capable of transmitting high conducting current.

### SUMMARY OF THE INVENTION

It is an object of the present invention to provide a power semiconductor device with high conducting current and low thermal resistance so as to enhance the heat-dissipating efficiency.

It is another object of the present invention to provide a circuit module having plural power semiconductor devices of the present invention so as to transmit more conducting current and efficiently dissipate heat through a first bus bar and a second bus bar.

In accordance with an aspect of the present invention, there is provided a power semiconductor device. The power semiconductor device includes a semiconductor chip, a first conductive piece, a second conductive piece and an encapsulating resin. The semiconductor chip includes a first electrode and a second electrode, wherein the first electrode is disposed on a first surface of the semiconductor chip, and the second electrode is disposed on the first surface or a second surface of the semiconductor chip. The first conductive piece includes a first contact part and a second contact part, wherein the second contact part of the first conductive piece is in contact with the first electrode of the semiconductor chip. The second conductive piece includes a third contact part and a fourth contact part, wherein the fourth contact part of the second conductive piece is in contact with the second electrode of the semiconductor chip. The encapsulating resin covers the semiconductor chip, a portion of the first conductive piece and a portion of the second conductive piece and exposes the first contact part of the first conductive piece and the third contact part of the second conductive piece, such that a conducting current is transmitted through the first contact part of the first conductive piece and the third contact part of the second conductive piece.

In accordance with another aspect of the present invention, there is provided a circuit module. The circuit module includes plural power semiconductor devices, a first bus bar, a second bus bar and a circuit board. The first bus bar is electrically connected to the first contact parts of the first conductive pieces of the power semiconductor devices. The second bus bar is electrically connected to the third contact parts of the second conductive pieces of the power semiconductor devices. The circuit board is electrically connected to the first bus bar and the second bus bar.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a cross-sectional view of a power semiconductor device called DirectFET developed by International Rectifier Corporation;

FIG. 2 is a schematic cross-sectional view of a power semiconductor device according to a first preferred embodiment of the present invention;

FIGS. 3(a)˜3(c) schematically illustrates a process for manufacturing the power semiconductor device shown in FIG. 2;

FIGS. 4(a), 4(b) and 4(c) schematically illustrate three different types of circuit modules assembled by plural power semiconductor devices of FIG. 2;

FIG. 5 is a schematic cross-sectional view of a power semiconductor device according to a second preferred embodiment of the present invention;

FIGS. 6(a)˜6(c) schematically illustrates a process for manufacturing the power semiconductor device shown in FIG. 5; and

FIG. 7 schematically illustrates the circuit module assembled by plural power semiconductor devices of FIG. 5.

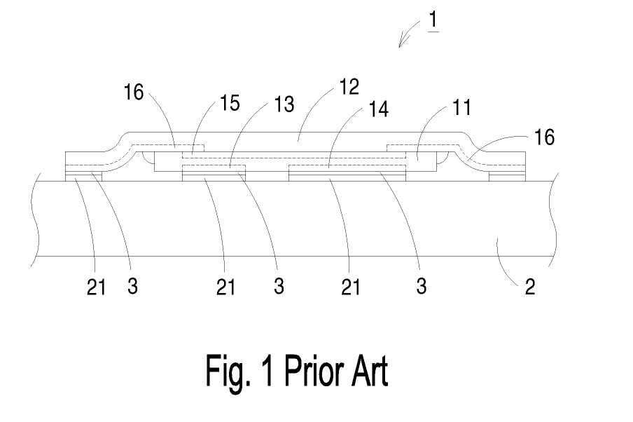

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

The present invention relates to a power semiconductor device having increased heat-dissipating efficiency and capable of transmitting high conducting current. The present invention also relates to a circuit module having such a power semiconductor device. The present invention will be illustrated by referring to power metal oxide semiconductor field effect transistors (power FETs) and power diodes. Nevertheless, the present invention can be applied to other power semiconductor devices.

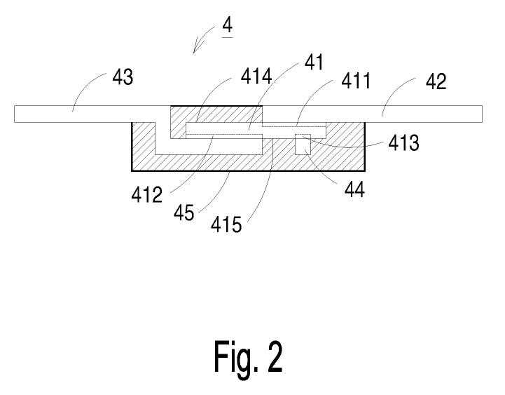

Referring to FIG. 2, a schematic cross-sectional view of a power semiconductor device according to a first preferred embodiment of the present invention is illustrated. In this embodiment, the power semiconductor device is for example a power metal oxide semiconductor field effect transistor. The power metal oxide semiconductor field effect transistor 4 includes a semiconductor chip 41, a first conductive piece 42, a second conductive piece 43, a conductive pin 44 and an encapsulating resin 45. The semiconductor chip 41 includes a first electrode 411, a second electrode 412 and a third electrode 413, which are drain, source and gate electrodes, respectively. The first electrode 411 is disposed on a first surface 414 of the semiconductor chip 41. It is preferred that the second electrode 412 and the third electrode 413 are disposed on a second surface 415 of the semiconductor chip 41. Alternatively, the second electrode 412 and the third electrode 413 may be disposed on the first surface 414 of the semiconductor chip 41.

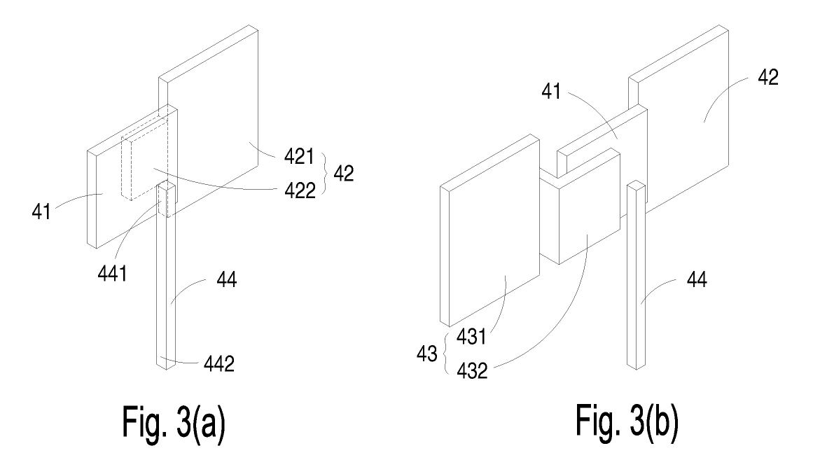

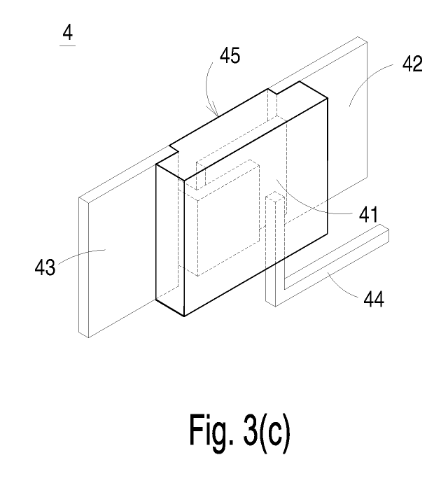

A process for manufacturing the power semiconductor device shown in FIG. 2 will be illustrated as follows with reference to FIGS. 3(a)˜3(c).

As shown in FIG. 2 and FIG. 3(a), the first conductive piece 42 includes a first contact part 421 and a second contact part 422. The second contact part 422 is extended from an edge of the first contact part 421. The second contact part 422 is in contact with the first electrode 411 of the semiconductor chip 41. It is preferred that the first contact part 421 and the second contact part 422 of the first conductive piece 42 are located at the same level. The conductive pin 44 is rectangular post having a first end 441 in contact with the third electrode 413 of the semiconductor chip 41 and a second end 442 to be electrically coupled to a corresponding contact portion (not shown) on a circuit board.

As shown in FIG. 2 and FIG. 3(b), the second conductive piece 43 also includes a third contact part 431 and a fourth contact part 432. The fourth contact part 432 is extended from an edge of the third contact part 431. The fourth contact part 432 of the second conductive piece 43 has a bent portion such that the third contact part 431 and the fourth contact part 432 are located at different levels. The fourth contact part 432 is in contact with the second electrode 412 of the semiconductor chip 41, which is disposed on the second surface 415 of the semiconductor chip 41.

As shown in FIG. 2 and FIG. 3(c), the whole semiconductor chip 41, a portion of the first conductive piece 42, a portion of the second conductive piece 43 and a portion of the conductive pin 44 are encapsulated by the encapsulating resin 45, thereby protecting the semiconductor chip 41 and fixing the first conductive piece 42, the second conductive piece 43 and the conductive pin 44. Depending on the layout configuration of the conductive trace on the circuit board, the conductive pin 44 may be bent at a specific angle. Meanwhile, the power metal oxide semiconductor field effect transistor 4 is fabricated.

In the above embodiments, the first contact part 421 of the first conductive piece 42, the third contact part 431 of the second conductive piece 43 and the upper surface of the encapsulating resin 45 are substantially flat with each other. In addition, the first contact part 421 of the first conductive piece 42 and the third contact part 431 of the second conductive piece 43 are extended from bilateral sides of the encapsulating resin 45. As a consequence, the conducting current may flow through the first contact part 421 of the first conductive piece 42 and the third contact part 431 of the second conductive piece 43.

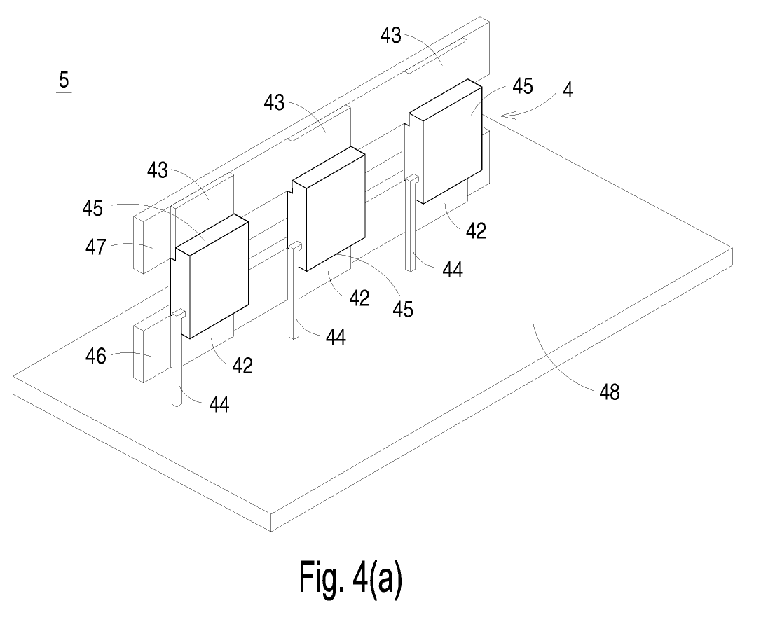

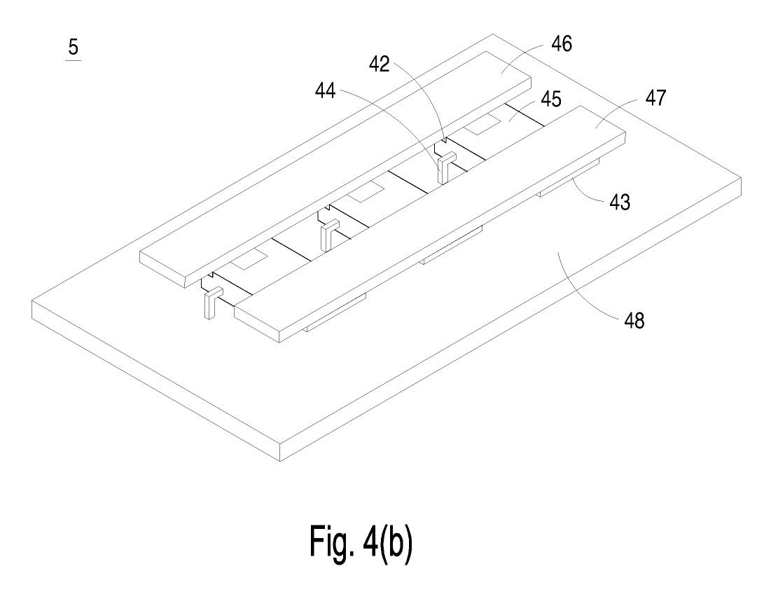

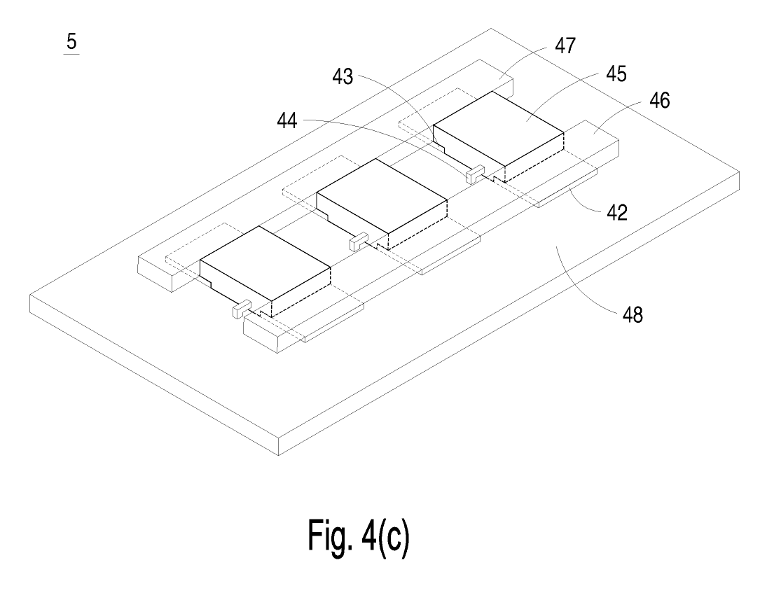

Referring to FIGS. 4(a), 4(b) and 4(c), three different types of circuit modules assembled by plural power semiconductor devices of FIG. 2 are illustrated.

In FIG. 4(a), the circuit module 5 includes plural power metal oxide semiconductor field effect transistors 4, a first bus bar 46, a second bus bar 47 and a circuit board 48. The first bus bar 46 and the second bus bar 47 are made of metallic material such as copper. The first bus bar 46 is electrically connected to the first conductive pieces 42 of the power metal oxide semiconductor field effect transistors 4. The second bus bar 47 is parallel with the first bus bar 46 and electrically connected to the second conductive pieces 43 of the power metal oxide semiconductor field effect transistors 4. The conductive pins 44 are electrically connected to the circuit board 48 in order to receive control signals from the circuit board 48 to control operations of the power metal oxide semiconductor field effect transistors 4. In response to the control signals, a conducting current is transmitted from the circuit board 48 to the second bus bar 47 through the conductive pins 44. Subsequently, the conducting current transmitted from the second bus bar 47 will flow through the second conductive pieces 43, the second electrodes 412 (e.g. source electrode), and the first electrodes 411 (e.g. drain electrode) to control operations of the power metal oxide semiconductor field effect transistors 4. Moreover, the first bus bar 46 and the second bus bar 47 will be electrically connected to other contact portions (not shown) on the circuit board 48 by electrical wire (not shown) so as to transmit the conducting current to the circuit board 48.

In FIG. 4(b), the circuit module 5 also includes plural power metal oxide semiconductor field effect transistors 4, a first bus bar 46, a second bus bar 47 and a circuit board 48. The operation principles of these components are similar to those shown in FIG. 4(a), and are not redundantly described herein. In this embodiment, the upper surfaces of the encapsulating resins 45 are distant from the circuit board 48. The first bus bar 46 and the second bus bar 47 are placed on the power metal oxide semiconductor field effect transistors 4 such that the first contact parts 421 of the first conductive pieces 42 are electrically connected to the first bus bar 46 and the third contact parts 431 of the second conductive pieces 43 are electrically connected to the second bus bar 47.

In FIG. 4(c), the circuit module 5 also includes plural power metal oxide semiconductor field effect transistors 4, a first bus bar 46, a second bus bar 47 and a circuit board 48. The operation principles of these components are similar to those shown in FIG. 4(a), and are not redundantly described herein. In this embodiment, the upper surfaces of the encapsulating resins 45 face to the circuit board 48. The first bus bar 46 and the second bus bar 47 are respectively placed on the first conductive pieces 42 and the second conductive pieces 43 such that the first contact parts 421 of the first conductive pieces 42 are electrically connected to the first bus bar 46 and the third contact parts 431 of the second conductive pieces 43 are electrically connected to the second bus bar 47.

In the above embodiments, the conducting current flows through the conductive pins 44, the first bus bar 46, the first conductive pieces 42 and the second conductive pieces 43 of the power metal oxide semiconductor field effect transistors 4 and the second bus bar 47. In other words, the heat generated from the semiconductor chips 41 will be readily conducted to the first bus bar 46 and the second bus bar 47, rather than directly conducted to circuit board 48. Moreover, since the first bus bar 46, the first conductive pieces 42 and the second conductive pieces 43 of the power metal oxide semiconductor field effect transistors 4 and the second bus bar 47 have large cross-sectional areas and are made of metallic material, the conducting current flowing therethrough is increased in comparison with the prior art. Due to the large heat transfer area and the high thermal conductivity, the heat-dissipating efficiency is enhanced. Alternatively, additional heat sinks (not shown) may be attached on the first bus bar 46 and the second bus bar 47, which have been subjected to insulating treatment, in order to increase heat-dissipating efficiency.

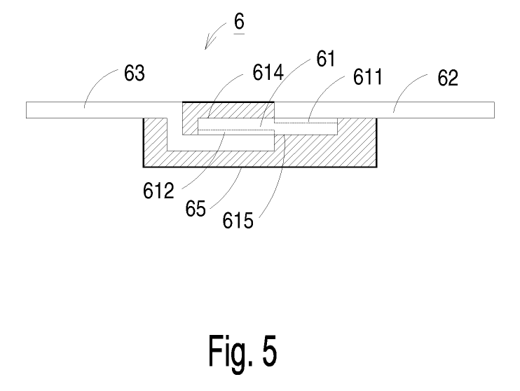

Referring to FIG. 5, a schematic cross-sectional view of a power semiconductor device according to a second preferred embodiment of the present invention is illustrated. In this embodiment, the power semiconductor device is for example a power diode. The power diode 6 includes a semiconductor chip 61, a first conductive piece 62, a second conductive piece 63 and an encapsulating resin 65. The semiconductor chip 61 includes a first electrode 611 and a second electrode 612, which are a P-type region and an N-type region, respectively. Alternatively, the first electrode 611 and a second electrode 612 are an N-type region and a P-type region, respectively. The first electrode 611 is disposed on a first surface 614 of the semiconductor chip 61. It is preferred that the second electrode 612 is disposed on a second surface 615 of the semiconductor chip 61. Alternatively, the first electrode 611 and the second electrode 612 may be disposed on the same surface of the semiconductor chip 61.

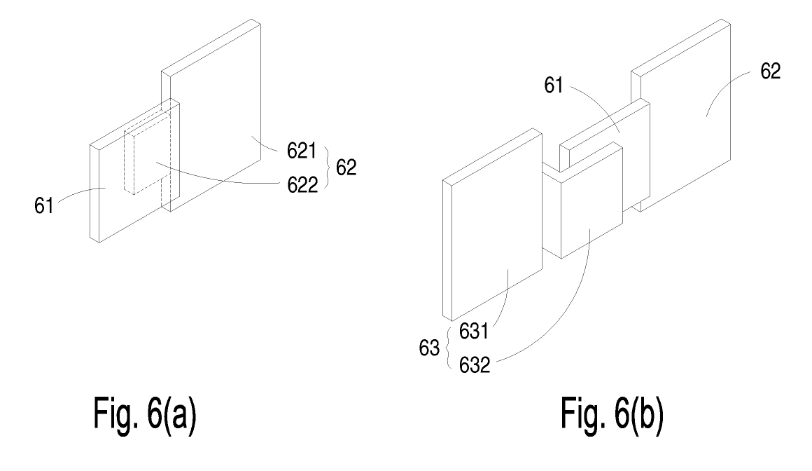

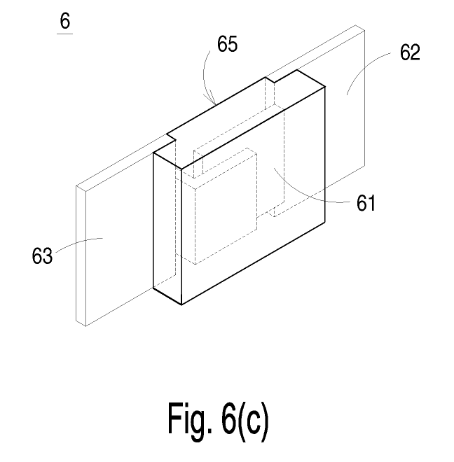

A process for manufacturing the power semiconductor device shown in FIG. 5 will be illustrated as follows with reference to FIGS. 6(a)˜6(c).

As shown in FIG. 5 and FIG. 6(a), the first conductive piece 62 includes a first contact part 621 and a second contact part 622. The second contact part 622 is extended from an edge of the first contact part 621. The second contact part 622 is in contact with the first electrode 611 of the semiconductor chip 61. It is preferred that the first contact part 621 and the second contact part 622 of the first conductive piece 62 are located at the same level.

As shown in FIG. 5 and FIG. 6(b), the second conductive piece 63 also includes a third contact part 631 and a fourth contact part 632. The fourth contact part 632 is extended from an edge of the third contact part 631. The fourth contact part 632 of the second conductive piece 63 has a bent portion such that the third contact part 631 and the fourth contact part 632 are located at different levels. The fourth contact part 632 is in contact with the second electrode 612 of the semiconductor chip 61, which is disposed on the second surface 615 of the semiconductor chip 61

As shown in FIG. 5 and FIG. 6(c), the whole semiconductor chip 61, a portion of the first conductive piece 62 and a portion of the second conductive piece 63 are encapsulated by the encapsulating resin 65, thereby protecting the semiconductor chip 61 and fixing the first conductive piece 62 and the second conductive piece 63. Meanwhile, the power diode 6 is fabricated.

In the above embodiments, the first contact part 621 of the first conductive piece 62, the third contact part 631 of the second conductive piece 63 and the upper surface of the encapsulating resin 65 are substantially flat with each other. In addition, the first contact part 621 of the first conductive piece 62 and the third contact part 631 of the second conductive piece 63 are extended from bilateral sides of the encapsulating resin 65. As a consequence, the conducting current may flow through the first contact part 621 of the first conductive piece 62 and the third contact part 631 of the second conductive piece 63.

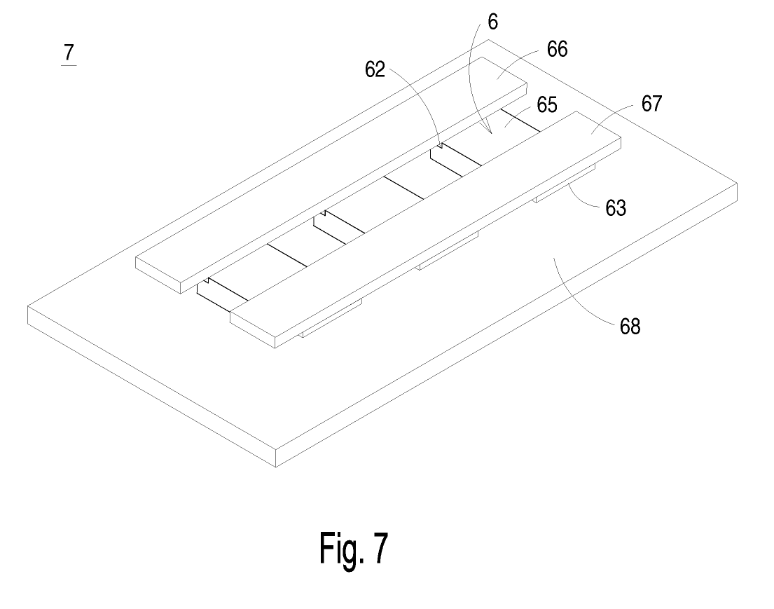

Referring to FIG. 7, a circuit module assembled by plural power semiconductor devices is illustrated. As shown in FIG. 7, the circuit module 7 includes plural power diodes 6, a first bus bar 66, a second bus bar 67 and a circuit board 68. The first bus bar 66 and the second bus bar 67 are made of metallic material such as copper. The first bus bar 66 is electrically connected to the first conductive pieces 62 of the power diodes 6. The second bus bar 67 is parallel with the first bus bar 66 and electrically connected to the second conductive pieces 63 of the power diodes 6. After a conducting current is transmitted from the circuit board 68 to the second bus bar 67, the conducting current will flow through the second conductive pieces 63, the second electrodes 612 and the first electrodes 611 of the semiconductor chip 61 to control operations of the power diodes 6. Moreover, the first bus bar 66 and the second bus bar 67 will be electrically connected to other contact portions (not shown) on the circuit board 68 by electrical wire (not shown) so as to transmit the conducting current to the circuit board 68.

In the above embodiments, the conducting current flows through the first bus bar 66, the first conductive pieces 62 and the second conductive pieces 63 of the power diodes 6 and the second bus bar 67. In other words, the heat generated from the semiconductor chips 61 will be readily conducted to the first bus bar 66 and the second bus bar 67, rather than directly conducted to circuit board 68. Moreover, since the first bus bar 66, the first conductive pieces 62 and the second conductive pieces 63 of the power diodes 6 and the second bus bar 67 have large cross-sectional areas and are made of metallic material, the conducting current flowing therethrough is increased in comparison with the prior art. Due to the large heat transfer area and the high thermal conductivity, the heat-dissipating efficiency is enhanced. Alternatively, additional heat sinks (not shown) may be attached on the first bus bar 66 and the second bus bar 67, which have been subjected to insulating treatment, in order to increase heat-dissipating efficiency.

From the above description, the conducting current allowable to be transmitted through the power semiconductor devices and the circuit module of the present invention is increased due to the large heat transfer areas and the high thermal conductivities of the first bus bar, the first conductive pieces, the second conductive pieces and the second bus bar. In addition, due to the large heat transfer area and the high thermal conductivity, the heat-dissipating efficiency is enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power semiconductor device comprising:
a semiconductor chip including a first electrode and a second electrode, wherein said first electrode is disposed on a first surface of said semiconductor chip, and said second electrode is disposed on said first surface or a second surface of said semiconductor chip;
a first conductive piece including a first contact part and a second contact part, wherein said second contact part of said first conductive piece is in contact with said first electrode of said semiconductor chip;
a second conductive piece including a third contact part and a fourth contact part, wherein said fourth contact part of said second conductive piece is in contact with said second electrode of said semiconductor chip; and
an encapsulating resin covering said semiconductor chip, a portion of said first conductive piece and a portion of said second conductive piece and exposing said first contact part of said first conductive piece and said third contact part of said second conductive piece, such that a conducting current is transmitted through said first contact part of said first conductive piece and said third contact part of said second conductive piece.

2. The power semiconductor device according to claim 1 wherein said power semiconductor device is a power metal oxide semiconductor field effect transistor, said power metal oxide semiconductor field effect transistor further includes a conductive pin and a third electrode, said third electrode is disposed on said first surface or said second surface of said semiconductor chip and electrically connected to conductive pin, and a portion of said conductive pin is encapsulated by said encapsulating resin.

3. The power semiconductor device according to claim 2 wherein said first electrode, said second electrode and said third electrode are drain, source and gate electrodes, respectively.

4. The process according to claim 2 wherein said second contact part of said first conductive piece is extended from an edge of said first contact part, said first contact part and said second contact part of said first conductive piece are located at the same level, and said fourth contact part of said second conductive piece is extended from an edge of said third contact part.

5. The process according to claim 2 wherein said conductive pin is a post having a first end in contact with said third electrode of said semiconductor chip and a second end to be electrically coupled to a corresponding contact portion on a circuit board.

6. The process according to claim 2 wherein said first contact part of said first conductive piece, said third contact part of said second conductive piece and the upper surface of said encapsulating resin are substantially flat with each other, and said first contact part of said first conductive piece and said third contact part of said second conductive piece are extended from bilateral sides of said encapsulating resin.

7. The power semiconductor device according to claim 1 wherein said power semiconductor device is a power diode, said first electrode is one of a P-type region and an N-type region, and said second electrode is one of an N-type region and a P-type region.

8. The process according to claim 7 wherein said second contact part of said first conductive piece is extended from an edge of said first contact part, said first contact part and said second contact part of said first conductive piece are located at the same level, and said fourth contact part of said second conductive piece is extended from an edge of said third contact part.

9. The process according to claim 7 wherein said first contact part of said first conductive piece, said third contact part of said second conductive piece and the upper surface of said encapsulating resin are substantially flat with each other, and said first contact part of said first conductive piece and said third contact part of said second conductive piece are extended from bilateral sides of said encapsulating resin.

10. A circuit module comprising:
plural power semiconductor devices, each of said power semiconductor devices including:
a semiconductor chip including a first electrode and a second electrode, wherein said first electrode is disposed on a first surface of said semiconductor chip, and said second electrode is disposed on said first surface or a second surface of said semiconductor chip;
a first conductive piece including a first contact part and a second contact part, wherein said second contact part of said first conductive piece is in contact with said first electrode of said semiconductor chip;
a second conductive piece including a third contact part and a fourth contact part, wherein said fourth contact part of said second conductive piece is in contact with said second electrode of said semiconductor chip; and
an encapsulating resin covering said semiconductor chip, a portion of said first conductive piece and a portion of said second conductive piece and exposing said first contact part of said first conductive piece and said third contact part of said second conductive piece, such that a conducting current is transmitted through said first contact part of said first conductive piece and said third contact part of said second conductive piece;
a first bus bar electrically connected to said first contact parts of said first conductive pieces of said power semiconductor devices;
a second bus bar electrically connected to said third contact parts of said second conductive pieces of said power semiconductor devices; and
a circuit board electrically connected to said first bus bar and said second bus bar.

11. The circuit module according to claim 10 wherein said power semiconductor device is a power metal oxide semiconductor field effect transistor, said power metal oxide semiconductor field effect transistor further includes a conductive pin and a third electrode, said third electrode is disposed on said first surface or said second surface of said semiconductor chip and electrically connected to conductive pin, and a portion of said conductive pin is encapsulated by said encapsulating resin.

12. The circuit module according to claim 11 wherein said first electrode, said second electrode and said third electrode are drain, source and gate electrodes, respectively.

13. The circuit module according to claim 11 wherein said second contact part of said first conductive piece is extended from an edge of said first contact part, said first contact part and said second contact part of said first conductive piece are located at the same level, and said fourth contact part of said second conductive piece is extended from an edge of said third contact part.

14. The circuit module according to claim 11 wherein said conductive pin is a post having a first end in contact with said third electrode of said semiconductor chip and a second end to be electrically coupled to a corresponding contact portion on a circuit board.

15. The circuit module according to claim 11 wherein said first contact part of said first conductive piece, said third contact part of said second conductive piece and the upper surface of said encapsulating resin are substantially flat with each other, and said first contact part of said first conductive piece and said third contact part of said second conductive piece are extended from bilateral sides of said encapsulating resin.

16. The circuit module according to claim 10 wherein said power semiconductor device is a power diode, said first electrode is one of a P-type region and an N-type region, and said second electrode is one of an N-type region and a P-type region.

17. The circuit module according to claim 16 wherein said second contact part of said first conductive piece is extended from an edge of said first contact part, said first contact part and said second contact part of said first conductive piece are located at the same level, and said fourth contact part of said second conductive piece is extended from an edge of said third contact part.

18. The circuit module according to claim 16 wherein said first contact part of said first conductive piece, said third contact part of said second conductive piece and the upper surface of said encapsulating resin are substantially flat with each other, and said first contact part of said first conductive piece and said third contact part of said second conductive piece are extended from bilateral sides of said encapsulating resin.

19. The circuit module according to claim 10 wherein said first bus bar and said second bus bar are arranged on said circuit board.

20. The circuit module according to claim 19 wherein said first bus bar and said second bus bar are parallel with each other.
